(19) United States
(12) Patent Application Publication
(10) Pub. No.: US 2015/0380267 A1
(43) Pub. Date: Dec. 31, 2015

(54) METHODS OF REMOVING A HARD MASK

(71) Applicant: Samsung Electronics Co., Ltd., Suwon-si (KR)

(72) Inventors: Je-Woo HAN, Hwaseong-si (KR); Gyung-Jin MIN, Seongnam-si (KR)

(21) Appl. No.: 14/706,975

(22) Filed: May 8, 2015

(30) Foreign Application Priority Data
Jun. 30, 2014 (KR) 10-2014-0080796

(51) Int. Cl. H01L 21/311; H01L 21/3065; H01L 21/308

(52) U.S. Cl. CPC H01L 21/31116; H01L 21/3086; H01L 21/3065

(57) ABSTRACT

In a method of removing a hard mask, a hard mask is formed on a substrate. A first plasma treatment is performed on the hard mask at a first temperature. A second plasma treatment is performed on the hard mask at a second temperature higher than the first temperature.

### CROSS-REFERENCE TO RELATED APPLICATION

This application claims priority under 35 USC §119 to Korean Patent Application No. 10-2014-0080796, filed on Jun. 30, 2014 in the Korean Intellectual Property Office (KIPO), the contents of which are herein incorporated by reference in their entirety.

### BACKGROUND

1. Field

Example embodiments relate to methods of removing a hard mask. More particularly, example embodiments relate to methods of removing a hard mask including carbon.

2. Description of the Related Art

When a semiconductor device is manufactured, a hard mask including carbon may be formed on an etching object layer, and the etching object layer may be etched using the hard mask as an etching mask to form minute patterns. The hard mask may be removed by, e.g., a plasma treatment, however, when an etching gas including fluorine is used in the etching process, fluorochemicals may be generated as etching by-products. The fluorochemicals may be deposited onto the hard mask to form a blocking layer, and thus the hard mask may not be completely removed but remain on the etching object layer. Particularly, the fluorochemicals are not chemically stable, and when the hard mask is removed at a high temperature, popping may occur from the blocking layer.

### SUMMARY

Example embodiments provide a method of manufacturing comprising the efficient removal of a hard mask.

According to example embodiments, there is provided a method of removing a hard mask. In the method, a hard mask is formed on a substrate. A first plasma treatment is performed on the hard mask at a first temperature. A second plasma treatment is performed on the hard mask at a second temperature higher than the first temperature.

In example embodiments, the hard mask may include carbon and boron. The boron may be included in an amount that may be in a range from 10 weight percent to about 50 weight percent.

In example embodiments, before forming the hard mask, an etching object layer may be formed on the substrate. The etching object layer is patterned using an etching gas including fluorine and the hard mask as an etching mask. For example, the etching gas may comprise fluorocarbon (CₓF_{y}) and/or hydrofluorocarbon (CₓH_{y}F_{z}).

In example embodiments, a blocking layer including fluorochemicals may be formed on the hard mask as the etching object layer is patterned.

In example embodiments, when the first plasma treatment is performed, the blocking layer may be removed.

In example embodiments, the first and second plasma treatments may be performed using different etching gases.

In example embodiments, the first plasma treatment may be performed using at least one of O₂ plasma and NF₃ plasma, and the second plasma treatment may be performed using H₂O plasma. Where carbon and boron may be included in the hard mask and they may be chemically reacted with a hydroxyl group (—OH) induced from the H2O plasma.

In example embodiments, the first temperature may be in a range of about 100° C. to about 300° C., and the second temperature may be in a range of about 400° C. to about 500° C.

In example embodiments, the first and second plasma treatments may be performed in-situ.

In example embodiments, the etching object layer may include at least one of silicon oxide and silicon nitride.

According to example embodiments, there is provided a method of removing a hard mask. In the method, a hard mask is formed on a substrate. The substrate is loaded onto an electrostatic chuck having a lift pin at an upper portion thereof in a chamber via an entrance at a side of the chamber, which may be the same chamber used for forming the hard mask. The lift pin may be moved in a first direction substantially perpendicular to a top surface of the substrate so that the substrate may be spaced apart from the electrostatic chuck. A first etching gas may be introduced into an inside of the chamber via a first inflow track of the chamber and a high frequency voltage may be applied to electrodes on an outer top surface of the chamber and under the electrostatic chuck, respectively, to perform a first plasma treatment, with the electrostatic chuck being heated to a first temperature by a temperature controller disposed at the chamber and connected to the electrostatic chuck. The lift pin may be moved in a second direction substantially opposite to the first direction so that the substrate may contact the electrostatic chuck. A second etching gas may be introduced into the inside of the chamber via a second inflow track of the chamber and a high frequency voltage may be applied to electrodes to perform a second plasma treatment, with the electrostatic chuck being kept at the first temperature.

In example embodiments, the first plasma treatment may be performed on the substrate at a second temperature lower than the first temperature, having the substrate spaced apart from the electrostatic chuck during the first plasma treatment. The temperature at the hard mask may be substantially the same as at the chuck.

In example embodiments, the hard mask may include carbon and boron.

In example embodiments, before forming the hard mask, an etching object layer may be formed on the substrate. The etching object layer may be patterned using an etching gas including fluorine and the hard mask as an etching mask.

In example embodiments, a blocking layer including fluorochemicals may be formed on the hard mask as the etching object layer is patterned, and when the first plasma treatment is performed, the blocking layer may be removed.

In example embodiments, the first etching gas may include at least one of O₂ gas and NF₃ gas, and the second etching gas may include H₂O gas.

According to example embodiments, there is provided a method of removing a hard mask as part of a method of manufacturing semiconductor device. In the method, a hard mask may be formed on a substrate. The substrate may be loaded onto a first electrostatic chuck in a first chamber via a first entrance at a side of the first chamber. A first etching gas may be introduced into an inside of the first chamber via a first inflow track of the first chamber and a high frequency voltage may be applied to first electrodes on an outer top surface of the first chamber and under the first electrostatic chuck, respectively, to perform a first plasma treatment, with the first electrostatic chuck being heated to a first temperature by a first temperature controller disposed at the first chamber and connected to the first electrostatic chuck. The substrate on which the first plasma treatment is performed may be loaded onto a second electrostatic chuck in a second chamber via a second entrance at a side of the second chamber. A second etching gas may be introduced into an inside of the second chamber via a second inflow track of the second chamber and a high frequency voltage may be applied to second electrodes on an outer top surface of the second chamber and under the second electrostatic chuck, respectively, to perform a second plasma treatment, with the second electrostatic chuck being heated to a second temperature higher than the first temperature by a second temperature controller disposed at the second chamber and connected to the second electrostatic chuck.

In example embodiments, the first temperature may be in a range of about 100° C. to about 300° C., and the second temperature may be in a range of about 400° C. to about 500° C. A third temperature higher than the second temperature may be used during the second plasma treatment. Lift pins may be used to elevate the substrate above the chuck.

In example embodiments, the hard mask may include carbon and boron. Before forming the hard mask, an etching object layer may be formed on the substrate. The etching object layer may be patterned using an etching gas including fluorine and the hard mask as an etching mask.

In example embodiments, a blocking layer including fluorochemicals may be formed on the hard mask as the etching object layer is patterned, and when the first plasma treatment is performed, the blocking layer may be removed.

According to example embodiments, a blocking layer that may be formed from etching by-products during the formation of patterns may be removed by a first plasma treatment at a relatively low temperature, and a hard mask serving as an etching mask for forming the patterns may be easily removed by a second plasma treatment. A ventilator may be used to purge each of the first and second plasma treatments by providing a driving energy.

The first and second plasma treatments may be performed in first and second chambers heated to different temperatures, or may be performed in the same chamber by changing a temperature of an electrostatic chuck. The first and second plasma treatments may be performed in-situ by moving a lift pin at an upper portion of the electrostatic chuck to control a temperature of the hard mask. Thus, even though a high temperature process is required for removing the hard mask, no popping and/or pollution may occur.

In other embodiments, the method of manufacturing may include removal of a second hard mask where etching selectivities of the first and second hard mask layers are different from each other but where the first and second hard mask layers are formed to include materials having high etching selectivities with respect to the etching object layer.

### BRIEF DESCRIPTION OF THE DRAWINGS

FIGS. 1 to 6 are cross-sectional views illustrating a method of removing a hard mask in accordance with example embodiments;

FIGS. 7 and 8 are cross-sectional views illustrating stages of a method of removing a hard mask in accordance with example embodiments;

FIGS. 9 and 10 are cross-sectional views illustrating stages of a method of removing a hard mask in accordance with example embodiments; and

FIGS. 11 to 19 are cross-sectional views illustrating stages of a method of manufacturing a semiconductor device in accordance with example embodiments.

### DETAILED DESCRIPTION OF EMBODIMENTS

Various example embodiments will be described more fully hereinafter with reference to the accompanying drawings, in which some example embodiments set forth herein. These example embodiments are just that—examples—and many implementations and variations are possible that do not require the details provided herein. It should also be emphasized that the disclosure provides details of alternative examples, but such listing of alternatives is not exhaustive. Furthermore, any consistency of detail between various examples should not be interpreted as requiring such detail—it is impracticable to list every possible variation for every feature described herein. The language of the claims should be referenced in determining the requirements of the invention.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first referenced element, component, region, layer or section discussed below could be referred to a second element, component, region, layer or section without departing from the teachings of the present disclosure.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present disclosure. As used herein, the singular forms “a,” “an” and “the” are intended to include the plural forms as well, unless the context clearly indicates otherwise. It will be further understood that the terms “comprises,” “comprising,” “includes,” and/or “including” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, deviations from the shapes in the illustrations as a result, for example, of manufacturing techniques and/or tolerances, are to be expected. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures may be schematic in nature and their shapes may not illustrate the actual shape of a region of a device.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

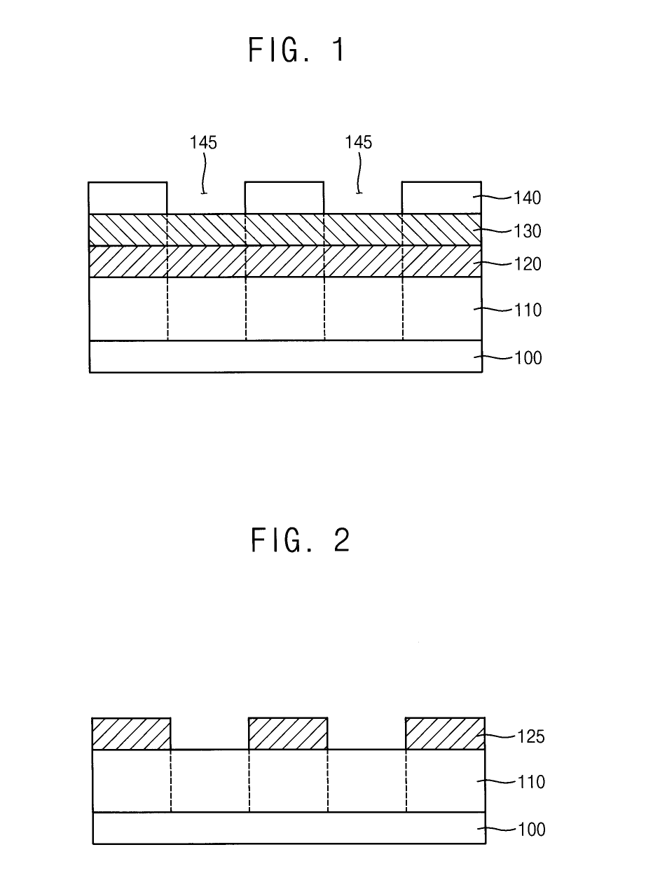

FIGS. 1 to 6 are cross-sectional views illustrating a method of removing a hard mask in accordance with example embodiments.

Referring to FIG. 1, an etching object layer 110, first and second hard mask layers 120 and 130, and a photoresist pattern 140 may be sequentially formed on a substrate 100, which may be loaded into a chamber (not shown). The photoresist pattern 140 may have an opening 145, partially exposing a top surface of the second hard mask layer 130.

The substrate 100 may be, e.g., a silicon substrate, a germanium substrate, a silicon-germanium substrate, a silicon-on-insulator (SOI) substrate, a germanium-on-insulator (GOI) substrate, etc.

The etching object layer 110 may be formed using silicon oxide and/or silicon nitride by, e.g., a chemical vapor deposition (CVD) process.

The first and second hard mask layers 120 and 130 may be formed to include materials having high etching selectivities with respect to the etching object layer 110, and the etching selectivities of the first and second hard mask layers 120 and 130 may be different from each other. In example embodiments, the first hard mask layer 120 may be formed to include carbon and boron, and the first hard mask layer 120 may include from about 10 weight percent to about 50 weight percent of boron. The second hard mask layer 130 may be formed to include silicon oxynitride or carbon.

According to desired patterns, the second hard mask layer 130 may not be formed, and the first hard mask layer 120 may be formed to include only carbon. Alternatively, at least one additional hard mask layer (not shown), including a material having an etching selectivity with respect to the etching object layer 110, may be further formed between the second hard mask layer 130 and the photoresist pattern 140.

Referring to FIG. 2, the second and first hard mask layers 130 and 120 may be sequentially etched using the photoresist pattern 140 as an etching mask. Thus, a first hard mask 125 and a second hard mask (not shown) may be formed on the etching object layer 110. The photoresist pattern 140 and the second hard mask may be removed by, e.g., a wet etch process.

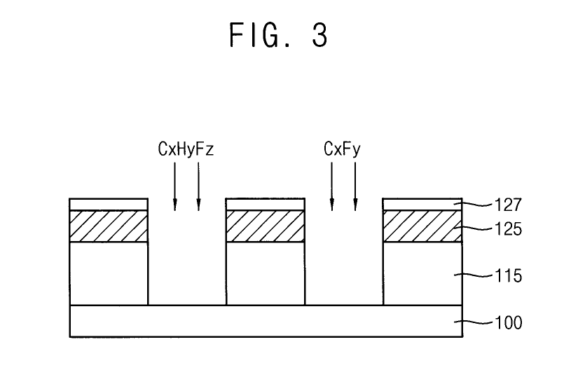

Referring to FIG. 3, the etching object layer 110 may be patterned using an etching gas including fluorine, and the first hard mask 125 may serve as an etching mask in the patterning process. Thus, the etching object layer 110 may be partially etched to form a pattern 115. In example embodiments, the etching gas may include fluorocarbon (CₓF_{y}) and/or hydrofluorocarbon (CₓH_{y}F_{z}).

Where the etching gas includes fluorine, by-products including fluorochemicals may be generated in the patterning process, which may be deposited onto the first hard mask 125 to form a blocking layer 127. Thus, the first hard mask 125 may not be removed by a plasma treatment after such a patterning process without first removing the blocking layer 127. This is because the by-products constituting the blocking layer 127 may not be chemically stable, and when the first hard mask 125 is attempted to be removed at a high temperature equal to or more than about 400° C. (e.g. in a plasma process), popping may occur from the blocking layer 127, causing pollution. Thus, a surface of the first hard mask 125 may be pre-treated before removing the first hard mask 125, so as to prevent defects and/or pollution from being generated.

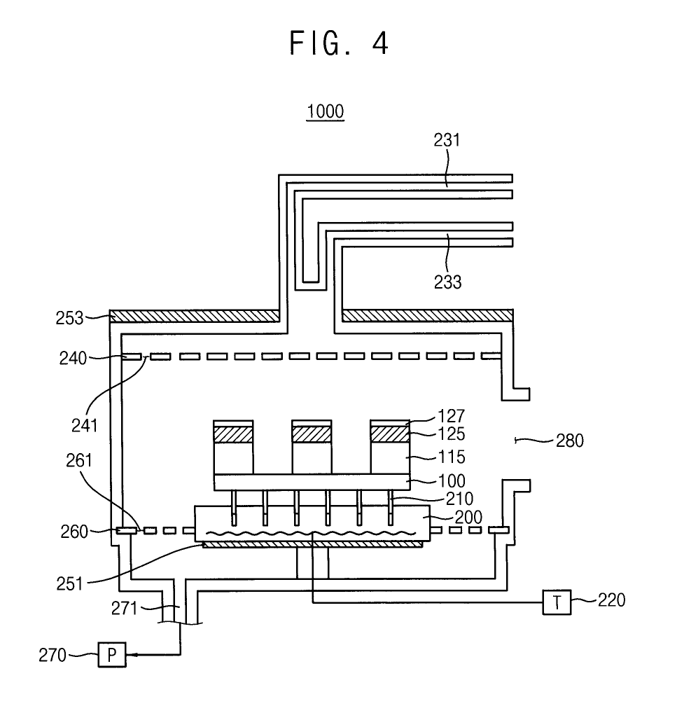

Referring to FIG. 4, the substrate 100 on which the first hard mask 125 and the pattern 115 are formed may be inserted into a first chamber 1000. In example embodiments, the first chamber 1000 may be different from the chamber in which the above processes illustrated with reference to FIGS. 1 to 3 may be performed. The first chamber 1000 may be the same as the chamber.

The first chamber 1000 may include a first entrance 280, a first electrostatic chuck 200, a first lift pin 210, a first temperature controller 220, first and second electrodes 251 and 253, first and second inflow tracks 231 and 233, a first diffusion panel 240, a first purification panel 260, a first ventilation duct 271 and a first ventilator 270, and the substrate 100 may be mounted on the first electrostatic chuck 200 and the first lift pin 210 at an upper portion of the first electrostatic chuck 200. A plurality of lift pins may be used, each of which lift and conduct a transfer of heat to a bottom surface of the substrate 100.

The first entrance 280 may be disposed at a first side of the first chamber 1000, and may provide a path for inserting and taking out the substrate 100.

The first electrostatic chuck 200 may be disposed at a central lower portion of an inside of the first chamber 1000, and support the substrate 100 mounted on a top surface thereof. The first electrostatic chuck 200 may include, e.g. aluminum, aluminum nitride, and the like.

The first lift pin 210 may be disposed at the upper portion of the first electrostatic chuck 200, and may move in a direction substantially perpendicular to the top surface of the first electrostatic chuck 200 so as to control a distance between the first electrostatic chuck 200 and the substrate 100. The first lift pin 210 may include, e.g., ceramic material.

The first temperature controller 220 may be electrically connected to and heat the first electrostatic chuck 200, and may include, e.g., a heater.

The first and second electrodes 251 and 253 may be disposed under the first electrostatic chuck 200 and on an outer top surface of the first chamber 1000, respectively, and may induce plasma from a processing gas in the first chamber 1000 when a high frequency voltage is applied thereto. The high frequency voltage may be a radio-frequency (RF) voltage. The high-frequency voltage may have a sinusoidal waveform, and a frequency in a range of 500 kHz to 200 MHz.

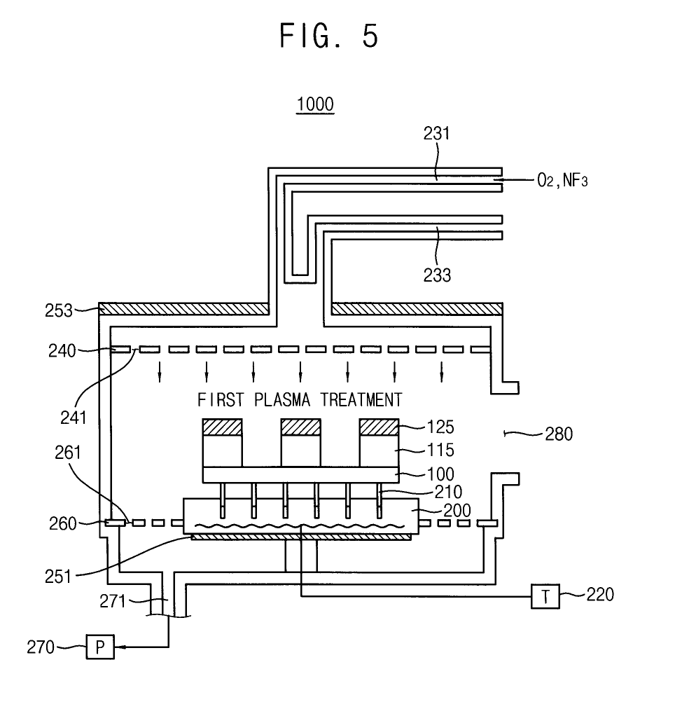

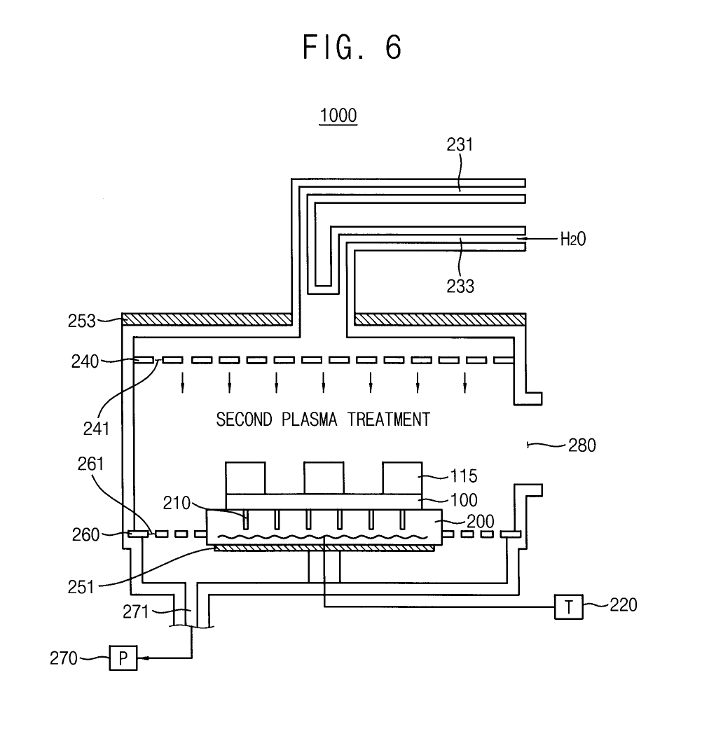

The first and second inflow tracks 231 and 233 may be connected to the top surface of the first chamber 1000, and may provide a path for introducing first and second processing gases used for first and second plasma treatments, respectively, into the chamber 1000 (refer to FIGS. 5 and 6).

The first diffusion panel 240 may be disposed at an upper portion of the inside of the first chamber 1000 adjacent the first and second inflow tracks 231 and 233. The first diffusion panel 240 may include a plurality of diffusion openings 241, and may uniformly diffuse the first and second processing gases introduced into the first chamber 1000.

The first purification panel 260 may be disposed at a lower portion of the inside of the first chamber 1000 adjacent a sidewall of the first electrostatic chuck 200, and include a plurality of ventilation openings 261.

The first ventilation duct 271 may be disposed at a bottom surface of the first chamber 1000 and may be connected to the first ventilator 270. The first purification panel 260 and the first ventilation duct 271 may provide a path for emitting reaction by-products remaining in the first chamber 1000 after the first and second plasma treatments.

The first ventilator 270 may provide a driving energy for a purge process after the first and second plasma treatments, and may include, e.g., a decompression pump.

In FIG. 4, only one first chamber 1000 is shown, however, the present inventive concept may not be limited thereto, and, e.g., a multi-chamber apparatus including a plurality of first chambers 1000 may be used in consideration of process efficiency and productivity.

The first lift pin 210 may be moved in a first direction substantially perpendicular to the top surface of the substrate 100 so that the substrate 100 may be spaced apart from the first electrostatic chuck 200, and the first electrostatic chuck 200 may be heated to a first temperature. In example embodiments, the first temperature may be in a range of about 400° C. to about 500° C.

The first hard mask 125 may be spaced apart from the first electrostatic chuck 200 at a distance incurred by the first lift pin 210, and thus may be heated to a second temperature lower than the first temperature, e.g., in a range of about 100° C. to about 300° C. Thus, even though the blocking layer 127 is formed on the first hard mask 125 due to the by-products, no popping due to the high temperature may occur.

Referring to FIG. 5, the first plasma treatment may be performed on the first hard mask 125.

In example embodiments, the first plasma treatment may be performed by introducing the first processing gas including at least one of oxygen (O₂) gas and nitrogen trifluoride (NF₃) gas into the first chamber 1000 via the first inflow track 231, and applying a high frequency voltage to the first and second electrodes 251 and 253 to induce plasma from the first processing gas in the first chamber 1000. In the first plasma treatment, O₂ plasma and/or NF₃ plasma may be generated, and may be reacted with the fluorochemicals (e.g., of the blocking layer) at the second temperature in the range of about 100° C. to about 300° C. Thus, the blocking layer 127 may be removed by the first plasma treatement.

A purge process may be performed using the first ventilator 270. Thus, by-products remaining in the first chamber 1000 after the first plasma treatment, e.g., an unreacted portion of the first processing gas and/or unreacted plasma may be easily emitted from the first chamber 1000 through the first ventilation duct 271.

Referring to FIG. 6, the first lift pin 210 may be moved in a second direction substantially perpendicular to the top surface of the substrate 100 and substantially opposite to the first direction such that the substrate 100 comes in contact with the first electrostatic chuck 200. The first hard mask 125 may be heated to a third temperature higher than the second temperature. In example embodiments, the first hard mask 125 may be heated to a temperature substantially the same as the first temperature to which the first electrostatic chuck 200 is heated in the process illustrated with reference to FIGS. 4 and 5, i.e., the temperature of about 400° C. to about 500° C., and the substrate 100 on which the first hard mask 125 is formed may not be spaced apart from, but instead contact the first electrostatic chuck 200 so as to be heated to the third temperature. Thus, the third temperature may be substantially the same as the first temperature.

The second plasma treatment may be performed to remove the first hard mask 125.

In example embodiments, the second plasma treatment may be performed by introducing the second processing gas including H₂O gas into the first chamber 1000 via the second inflow track 233, and applying a high frequency voltage to the first and second electrodes 251 and 253 to induce H₂O plasma from the second processing gas in the first chamber 1000. That is, carbon and boron included in the first hard mask 125 may be chemically reacted with a hydroxyl group (—OH) induced from the H₂O plasma at the third temperature of about 400° C. to about 500° C. to be removed.

As illustrated above, even though the blocking layer 127 may be formed on the first hard mask 125 due to the by-products when the pattern 115 is formed, the blocking layer 127 can be easily removed by the first plasma treatment at the relatively low first temperature, and the first hard mask 125 may be easily removed by the second plasma treatment at the relatively high third temperature.

When the second plasma treatment is required to be performed at a high temperature above about 400° C. because of the composition of the first hard mask 125, popping may occur from the blocking layer 127, however, the first lift pin 210 may be moved in the first chamber 1000 to control the temperature of the first hard mask 125, so that the popping and pollution may be prevented. Additionally, even without changing the temperature of the first chamber 1000 and/or the first electrostatic chuck 200 (e.g., by altering the temperature of the first chamber 1000 by adjusting the first temperature controller 220) in order to control the temperature of the first hard mask 125, the first and second plasma treatments may be performed in-situ so as to enhance the process efficiency and the productivity. This in-situ process may include performing the first and second plasma treatments in the same processing chamber without removing the substrate, and without creating a vacuum break between the first and second treatments. Reaching the first, second, and third temperatures may therefore be accomplished in a single chamber by use of the first lift pin 210 to adjust the height of the substrate 100 above the heated electrostatic chuck 200. In this example, the farther the substrate is positioned away from the heated electrostatic chuck 200, the lower the substrate 100 temperature is made (which may include any existing hard mask layer (e.g. the first hard mask 125 with blocking layer 127).

Etching object layer 110 may have been previously formed on the substrate 100 and may now be patterned using the first hard mask 125 as an etching mask to form the pattern 115. The first hard mask 125 may then be removed. However, the present disclosure is not limited to removing the first hard mask 125 that has served as an etching mask. The present inventive concept may be applied to any type of hard mask that includes carbon and/or boron, and the hard mask may not serve as an etching mask but may serve as, e.g., a polishing endpoint in a planarization process.

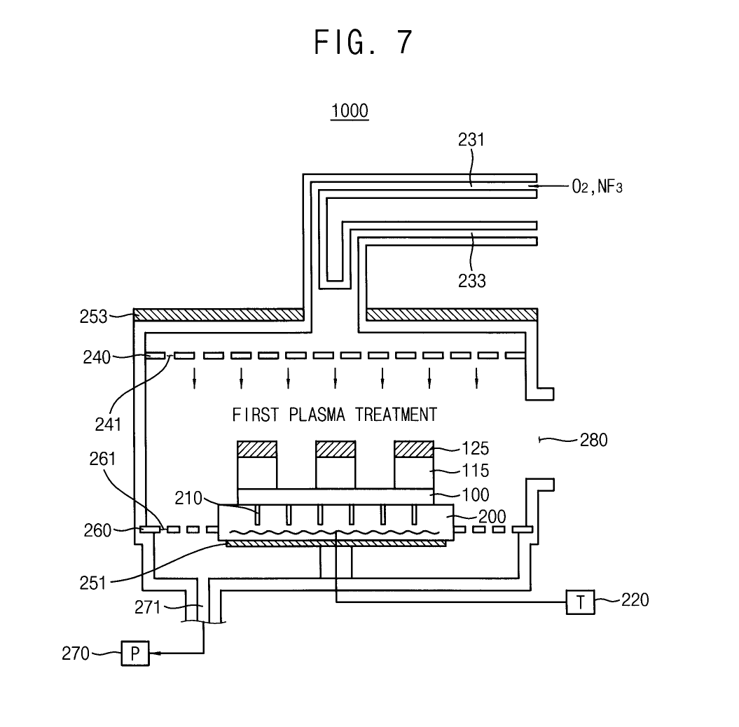

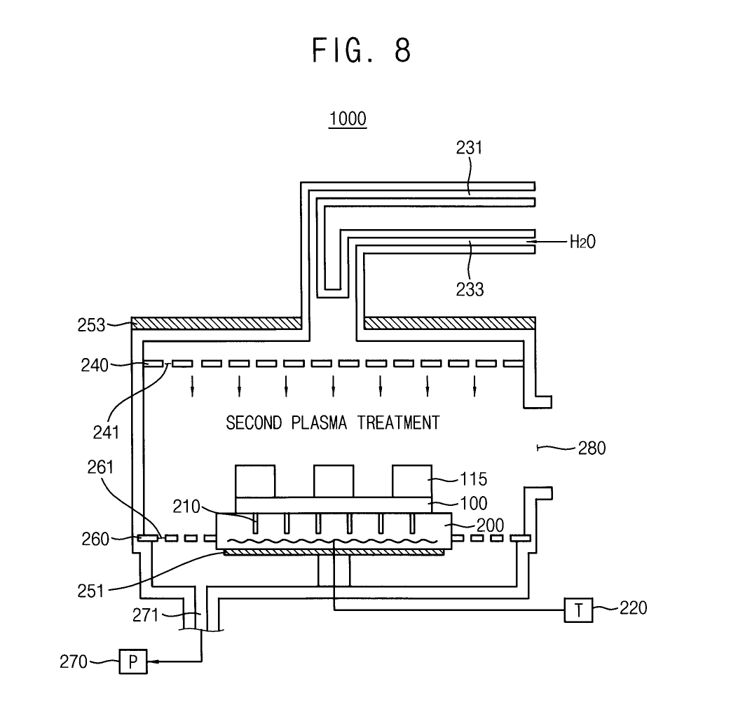

FIGS. 7 and 8 are cross-sectional views illustrating stages of a method of removing a hard mask in accordance with example embodiments. This method may include processes substantially the same as those illustrated with reference to FIGS. 1 to 6. Thus, like reference numerals refer to like elements, and detailed descriptions thereon are omitted herein.

First, processes substantially the same as or similar to those illustrated with reference to FIGS. 1 to 3 may be performed. Thus, a pattern 115 and a first hard mask 125 may be sequentially formed on a substrate 100 loaded into a chamber (not shown). A blocking layer 127 including fluorochemicals may be formed on the first hard mask 125 due to the formation of by-products when the pattern 115 is formed.

Referring to FIG. 7, the substrate 100 having the first hard mask 125 and the pattern 115 thereon may be inserted into a first chamber 1000 having a first entrance 280, a first electrostatic chuck 200, a first lift pin 210, a first temperature controller 220, first and second electrodes 251 and 253, first and second inflow tracks 231 and 233, a first diffusion panel 240, a first purification panel 260, a first ventilation duct 271 and a first ventilator 270. As mentioned above, the first chamber 1000 may be different from or the same as the chamber. The substrate 100 may be mounted on the first electrostatic chuck 200 and the first lift pin 210. The first lift pin 210 may be one of a plurality of lift pins.

The first electrostatic chuck 200 may be heated to a second temperature in a range of about 100° C. to about 300° C. and a first plasma treatment may be performed on the first hard mask 125.

As the first electrostatic chuck 200 is heated to the second temperature, the first hard mask 125 on the substrate 100 contacting the first electrostatic chuck 200 may be also heated to the second temperature, and thus no popping may occur as a result of the removal of the blocking layer 127 that had been formed on the first hard mask 125.

In example embodiments, the first plasma treatment may be performed by processes substantially the same as or similar to those illustrated with reference to FIG. 5. That is, the first plasma treatment may be performed at the second temperature in a range of about 100° C. to about 300° C. using O₂ plasma and/or NF₃ plasma. Thus, the blocking layer 127 may be removed.

Referring to FIG. 8, a second plasma treatment may be performed to remove the first hard mask 125.

In example embodiments, the second plasma treatment may be performed by processes substantially the same as or similar to those illustrated with reference to FIG. 6. The second plasma treatment may be performed, e.g., using H₂O plasma.

When the second plasma treatment is performed, a temperature higher than the second temperature at which the first plasma treatment is performed, e.g., a temperature of more than about 400° C. may be optimal to remove the first hard mask 125, according to a concentration of boron in the first hard mask 125. Thus, before providing the H₂O plasma onto the substrate 100, the first electrostatic chuck 200 may be heated to a third temperature, e.g., in a range of about 400° C. to about 500° C., and the second plasma treatment may be performed under this temperature condition.

In the method of removing the first hard mask 125 illustrated with reference to FIGS. 7 and 8, the first electrostatic chuck 200 may include the first lift pin 210, however, unlike the method illustrated with reference to FIGS. 1 to 6, the substrate 100 may not be spaced apart from the first electrostatic chuck 200 by the first lift pin 210, and popping may be prevented by controlling the temperature heating the first electrostatic chuck 200. Thus, the first electrostatic chuck 200 may not include the first lift pin 210.

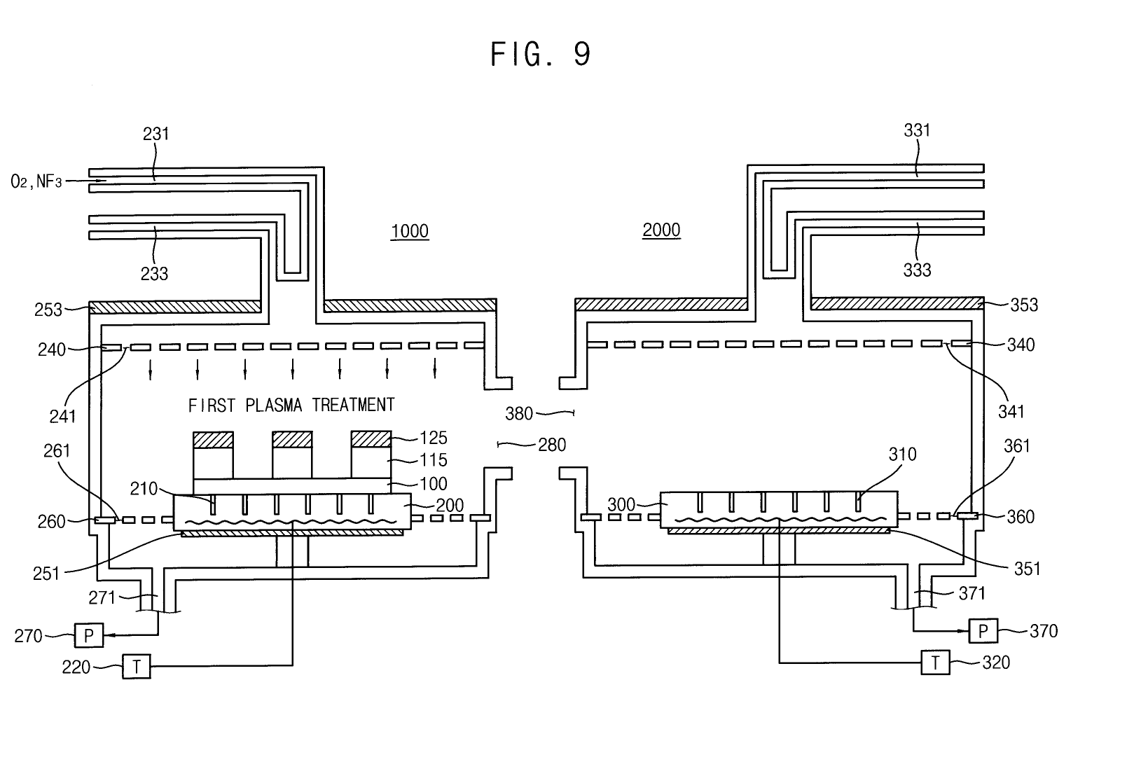

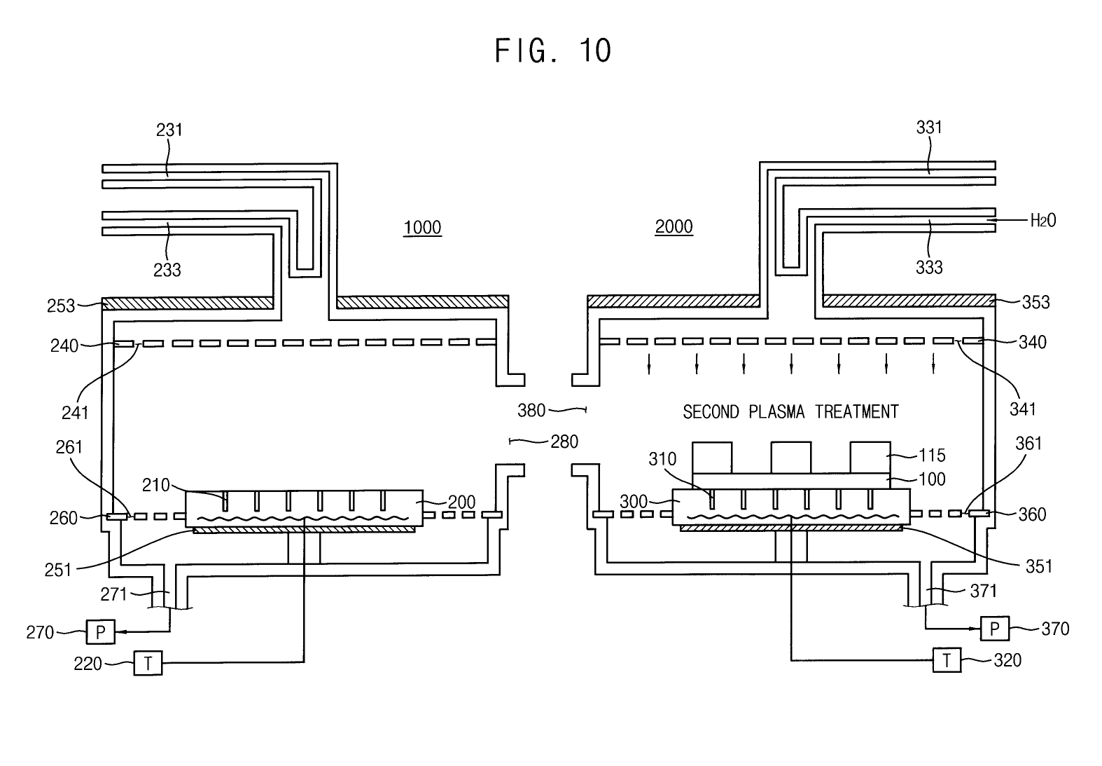

FIGS. 9 and 10 are cross-sectional views illustrating stages of a method of removing a hard mask in accordance with example embodiments. This method may include processes substantially the same as or similar to those illustrated with reference to FIGS. 1 to 6. Thus, like reference numerals refer to like elements, and detailed descriptions thereon are omitted herein.

First, processes substantially the same as or similar to those illustrated with reference to FIGS. 1 to 3 may be performed. Thus, a pattern 115 and a first hard mask 125 may be sequentially formed on a substrate 100 loaded into a chamber (not shown). A blocking layer 127 including fluorochemicals may be formed on the first hard mask 125 due to the formation of by-products when the pattern 115 is formed.

Referring to FIG. 9, a first plasma treatment may be performed on the substrate 100 having the first hard mask 125 and the pattern 115 thereon in a multi-chamber apparatus having first and second chambers 1000 and 2000. The substrate 100 may be inserted into the first chamber 1000 to be loaded onto the first electrostatic chuck 200 and the first lift pin 210.

The first and second chambers 1000 and 2000 may be adjacent to each other in the multi-chamber apparatus, and may include substantially the same elements. That is, the first chamber 1000 may include a first entrance 280, a first electrostatic chuck 200, a first lift pin 210, a first temperature controller 220, first and second electrodes 251 and 253, first and second inflow tracks 231 and 233, a first diffusion panel 240, a first purification panel 260, a first ventilation duct 271 and a first ventilator 270, and the second chamber 2000 may include a second entrance 380, a second electrostatic chuck 300, a second lift pin 310, a second temperature controller 320, third and fourth electrodes 351 and 353, third and fourth inflow tracks 331 and 333, a second diffusion panel 340, a second purification panel 360, a second ventilation duct 371 and a second ventilator 370. Each element of the second chamber 2000 may be substantially the same as that of the first chamber 1000. In FIG. 9, only the first and second chambers 1000 and 2000 are shown, however, the multi-chamber apparatus may include at least one more chamber in consideration of process efficiency and productivity. The first and second chambers 1000 and 2000 may be different from or the same as the chambers disclosed elsewhere herein.

In example embodiments, the first plasma treatment may be performed by processes substantially the same as or similar to those illustrated with reference to FIG. 5. That is, the first plasma treatment may be performed by introducing a first processing gas including at least one of oxygen (O₂) gas and nitrogen trifluoride (NF₃) gas into the first chamber 1000 via the first inflow track 231, and using plasma induced from the first processing gas in the first chamber 1000 at a second temperature in the range of about 100° C. to about 300° C. Thus, the blocking layer 127 may be removed.

When the first plasma treatment is performed, the substrate 100 may contact the first electrostatic chuck 200 in the first chamber 1000 as shown in FIG. 9, and the first electrostatic chuck 200 may be heated to the second temperature of about 100° C. to about 300° C. by the first temperature controller 220.

Alternatively, as shown in FIG. 4, the first lift pin 210 at an upper portion of the first electrostatic chuck 200 may be moved in the first direction so that the substrate 100 may be spaced apart from the first electrostatic chuck 200, and in this case, the first electrostatic chuck 200 may be heated to the first temperature higher than the second temperature, i.e., a temperature in a range of about 400° C. to about 500° C. by the first temperature controller 220. Since the first hard mask 125 is spaced apart from the first electrostatic chuck 200 at a predetermined distance, it may be heated to a temperature lower than the second temperature, e.g., in a range of about 100° C. to about 300° C. The predetermined distance may ensure that the substrate 100 (and thus heat the hard mask 125) be heated to the second, lower temperature, without having to change the temperature at the first temperature controller 220, even though the temperature at the first electrostatic chuck 200 and in the first chamber 1000 may be at the first, higher temperature.

In either case, i.e. in which the substrate 100 contacts or is spaced apart from the first electrostatic chuck 200, the first hard mask 125 in these examples may be heated to the relatively low second temperature, e.g., in a range of about 100° C. to about 300° C. Thus, even though the blocking layer 127 may be formed on the first hard mask 125 in the patterning process, the blocking layer 127 may be easily removed with no popping by the first plasma treatment.

Referring to FIG. 10, the first substrate 100 having the first hard mask 125 and the pattern 115 thereon may be moved to an inside of the second chamber 2000 from the first chamber 1000, a second plasma treatment may be performed on the substrate 100. The inside of the second chamber 2000 may be heated to a third temperature higher than the temperature of the first chamber 1000 by the second temperature controller 320. For example, the third temperature may be in a range of about 400° C. to about 500° C.

In example embodiments, the second plasma treatment may be performed by processes substantially the same as or similar to those illustrated with reference to FIG. 6. That is, the second plasma treatment may be performed by introducing a second processing gas including H₂O gas into the second chamber 2000 via the fourth inflow track 333, and using H₂O plasma induced from the second processing gas in the second chamber 2000. Thus, the first hard mask 125 may be removed.

In the second plasma treatment, the substrate 100 may contact the second electrostatic chuck 300 in the second chamber 2000 as shown in FIG. 10, and the second electrostatic chuck 300 may be heated to the third temperature, e.g., in a range of about 400° C. to about 500° C. by the second temperature controller 320.

Alternatively, the second lift pin 310 at an upper portion of the second electrostatic chuck 300 may be moved in the first direction so that the substrate 100 may be spaced apart from the second electrostatic chuck 3000, which may be similar to that of FIG. 4, however, in this case, the second electrostatic chuck 300 may be heated to a fourth temperature higher than the third temperature, e.g., in a range of about 500° C. to about 700° C. by the second temperature controller 320. Thus, the substrate 100 may be spaced apart from the second electrostatic chuck 300 at a predetermined distance to cause heating of the first hard mask 125 to the third temperature, lower than the fourth temperature, e.g., in a range of about 400° C. to about 500° C.

As illustrated above, the blocking layer 127 that may be formed when the pattern 115 is formed due to the formation of etching by-products may be removed by the first plasma treatment at a relatively low temperature, and the first hard mask 125 may be easily removed by the second plasma treatment at a relatively high temperature.

The first and second plasma treatments may be performed in the first and second chambers 1000 and 2000, respectively, at different temperatures, and the temperature of the first hard mask 125 may be controlled in the first and second plasma treatments so that no popping and pollution may occur.

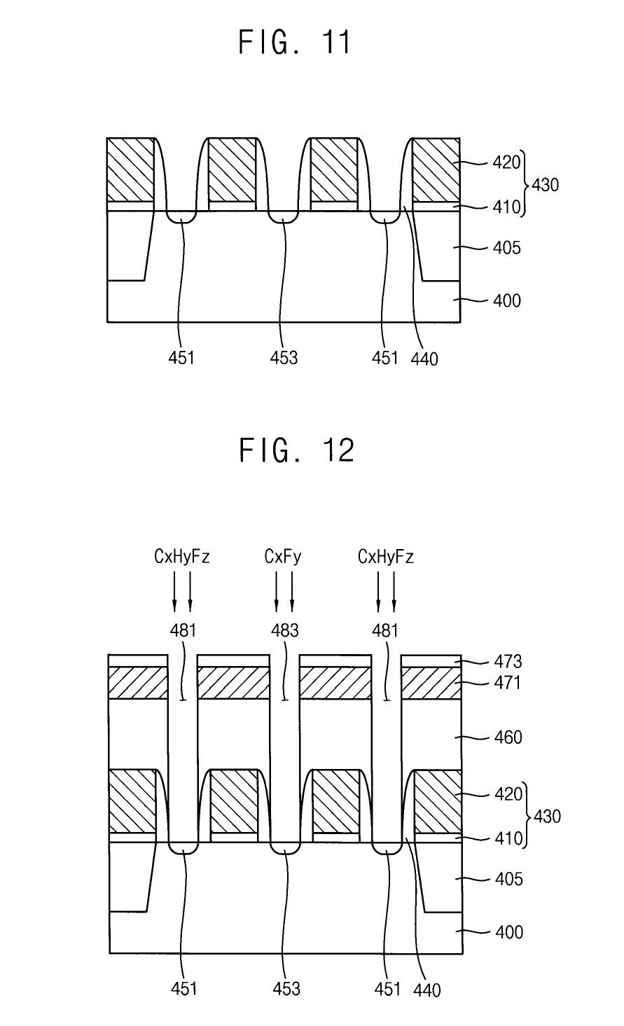

FIGS. 11 to 19 are cross-sectional views illustrating stages of a method of manufacturing a semiconductor device in accordance with example embodiments. This method may include processes substantially the same as or similar to the method of removing the hard mask illustrated with reference to FIGS. 1 to 6, FIGS. 7 to 8, or FIGS. 9 to 10, and thus detailed descriptions thereon are omitted herein.

Referring to FIG. 11, a gate structure 430 and a spacer 440 may be formed on a substrate 400 having an isolation layer pattern 405 thereon, and first and second impurity regions 451 and 453 may be formed at upper portions of the substrate 400 adjacent thereto. The gate structure 430 and the first and second impurity regions 451 and 453 may define a transistor, and the first and second impurity regions 451 and 453 may serve as source/drain regions of the transistor.

The substrate 400 may be a silicon substrate, a germanium substrate, a silicon-germanium substrate, a silicon-on-insulator (SOI) substrate, a germanium-on-insulator (GOI) substrate, etc.

The isolation layer pattern 405 may be formed by forming a trench (not shown) at an upper portion of the substrate 400, forming an isolation layer on the substrate 400 to fill the trench, and planarizing the isolation layer until a top surface of the substrate 400 may be exposed. The isolation layer may be formed to include an oxide, e.g., silicon oxide.

The gate structure 430 may be formed by sequentially forming a gate insulation layer, a gate electrode layer and a mask (not shown) on the substrate 400, sequentially patterning the gate electrode layer and the gate insulation layer using the mask as an etching mask, and removing the mask by, e.g., a wet etch process. Thus, the gate structure 400 may be formed to include a gate insulation layer pattern 410 and a gate electrode 420 sequentially stacked on the substrate 400. The gate insulation layer pattern 410 may be formed to include an oxide, e.g., silicon oxide, and the gate electrode 420 may be formed to include doped polysilicon, a metal, e.g., tungsten, etc.

The spacer 440 may be formed by forming a spacer layer on the substrate 400 to cover the gate structure 430, and anisotropically etching the spacer layer. Thus, the spacer 440 may be formed on a sidewall of the gate structure 430. The spacer 440 may be formed to include a nitride, e.g., silicon nitride.

The first and second impurity regions 451 and 453 may be formed by implanting impurities onto upper portions of the substrate 400 having the gate structure 430 and the spacer 440 thereon. The first and second impurity regions 451 and 453 may be formed to include n-type impurities, e.g., phosphorus, arsenic, etc., or p-type impurities, e.g., boron, gallium, etc.

Alternatively, after forming the first and second impurity regions 451 and 453, the gate structure 430 and the spacer 440 may be formed.

Referring to FIG. 12, processes substantially the same as or similar to those illustrated with reference to FIGS. 1 to 3 may be performed. Thus, a first insulating interlayer 460 may be formed on the substrate 400 to sufficiently cover the transistor, and first and second contact holes 481 and 483 may be formed through the first insulating interlayer 460 to expose top surfaces of the first and second impurity regions 451 and 453.

The first insulating interlayer 460 may be formed to include an insulating material, e.g., silicon oxide and/or silicon nitride.

In example embodiments, the first and second contact holes 481 and 483 may be formed by forming a third hard mask 471 on the first insulating interlayer 460 to partially expose a top surface of the first insulating interlayer 460, and etching the first insulating interlayer 460 using an etching gas including fluorine using the third hard mask 471 as an etching mask. The third hard mask 471 may be formed to include carbon and boron, and the third hard mask layer 471 may include from about 10 weight percent to about 50 weight percent of boron. The etching gas may include fluorocarbon (CₓF_{y}) and/or hydrofluorocarbon (CₓH_{y}F_{z}).

In the etching process, etching by-products including fluorochemicals may be generated from the etching gas, and may form a blocking layer 473 on the third hard mask 471. Thus, the third hard mask 471 may not be removed but remain on the first insulating interlayer 460 after the etching process. When a removal process is performed on the third hard mask 471 at a high temperature of more than about 400° C., popping may occur from the blocking layer 473.

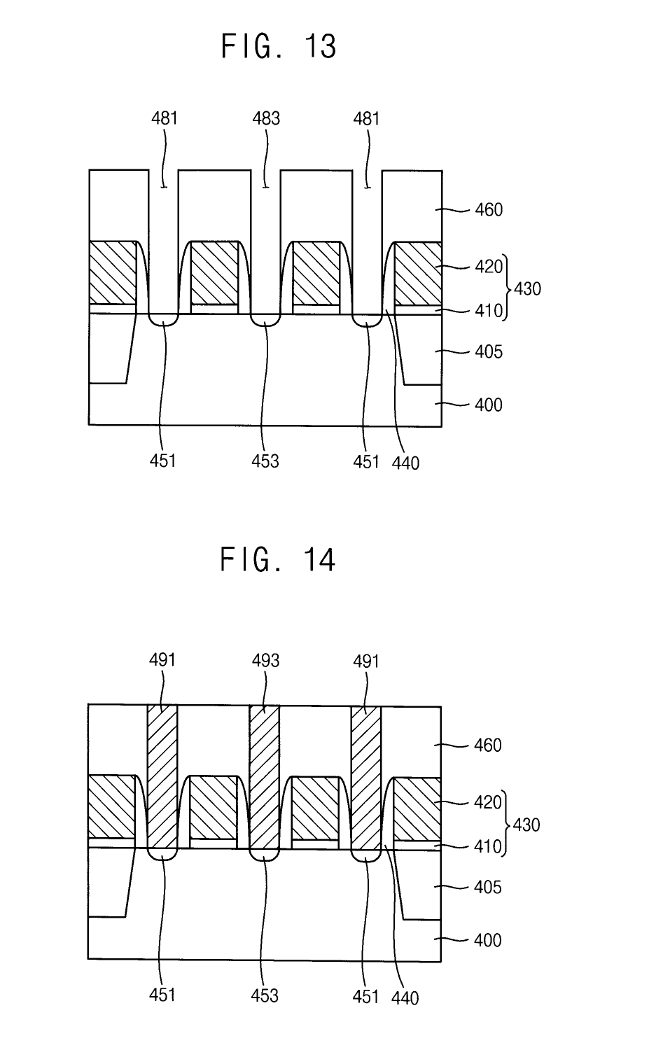

Referring to FIG. 13, processes substantially the same as or similar to those illustrated with reference to FIGS. 4 to 6, FIGS. 7 to 8, or FIGS. 9 to 10 may be performed to remove the blocking layer 473 and the third hard mask 471.

That is, a first plasma treatment may be performed on the third hard mask 471 to remove the blocking layer 473 and/or the etching by-products, and a second plasma treatment may be performed to remove the third hard mask 471. In example embodiments, the first plasma treatment may be performed at the second temperature, e.g., in a range of about 100° C. to about 300° C. using O₂ plasma and/or NF₃ plasma, and the second plasma treatment may be performed at the third temperature, e.g., in a range of about 400° C. to about 500° C. using H₂O plasma.

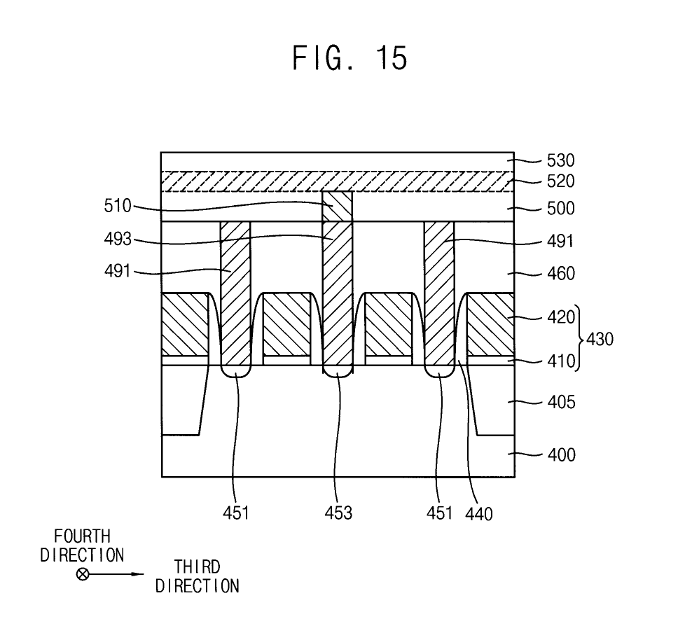

Referring to FIG. 14, first and second contact plugs 491 and 493 may be formed to fill the first and second contact holes 481 and 483, respectively.

In example embodiments, the first and second contact plugs 491 and 493 may be formed by forming a first conductive layer on the substrate 400 and the first insulating interlayer 460 to sufficiently fill the first and second contact holes 481 and 483, and planarizing the first conductive layer until a top surface of the first insulating interlayer 460 is exposed by a chemical mechanical polishing (CMP) process and/or an etch back process. Thus, the first and second contact plugs 491 and 493 may contact the top surfaces of the first and second impurity regions 451 and 453, respectively, and electrically connected to the transistor.

The first and second contact plugs 491 and 493 may be formed to include doped polysilicon, a metal, e.g., tungsten, etc.

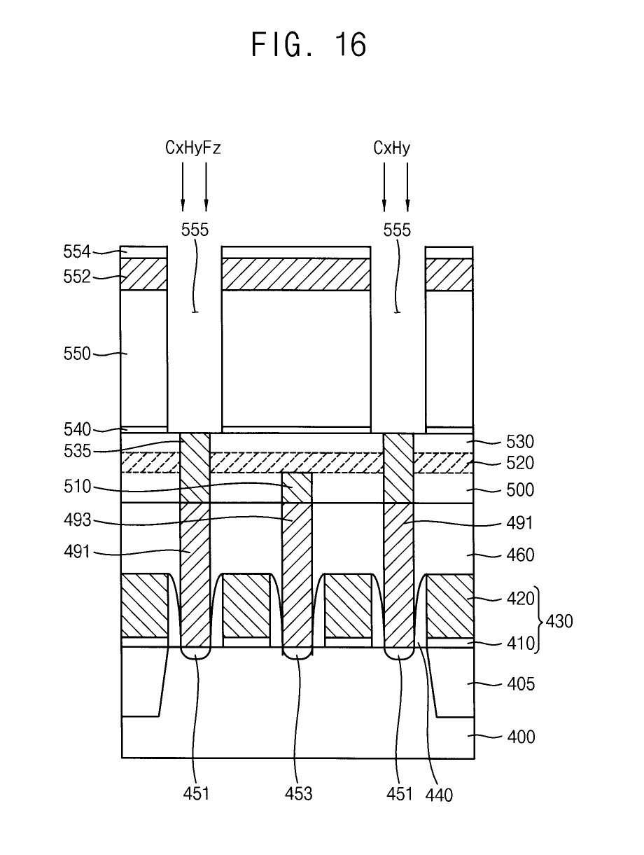

Referring to FIG. 15, a second insulating interlayer 500 may be formed on the first insulating interlayer 460 and the first and second contact plugs 491 and 493, a bit line contact 510 may be formed through the second insulating interlayer 500 to contact a top surface of the second contact plug 493, and a bit line 520 contacting the bit line contact 510 and a third insulating interlayer 530 covering the bit line 520 may be formed on the second insulating interlayer 500. Thus, the bit line contact 510 and the bit line 520 may be electrically connected to the transistor.

In example embodiments, the bit line contact 510 may be formed by partially removing the second insulating interlayer 500 to form a first opening (not shown) exposing the top surface of the second contact plug 493, forming a second conductive layer on the second contact plug 493 and the second insulating interlayer 500 to sufficiently fill the first opening, and planarizing the second conductive layer until a top surface of the second insulating interlayer 500 may be exposed.

In example embodiments, the bit line 520 may be formed by forming a third conductive layer on the second insulating interlayer 500 to contact the bit line contact 510, and patterning the third conductive layer. Thus, the bit line 520 may be formed to extend in a third direction substantially parallel to a top surface of the substrate 400, and a plurality of bit lines 520 may be formed in a fourth direction substantially parallel to the top surface of the substrate 400 and substantially perpendicular to the third direction.

The bit line contact 510 and the bit line 520 may be formed to include doped polysilicon, a metal, e.g., tungsten, etc. The second and third insulating interlayers 500 and 530 may be formed to include silicon oxide and/or silicon nitride.

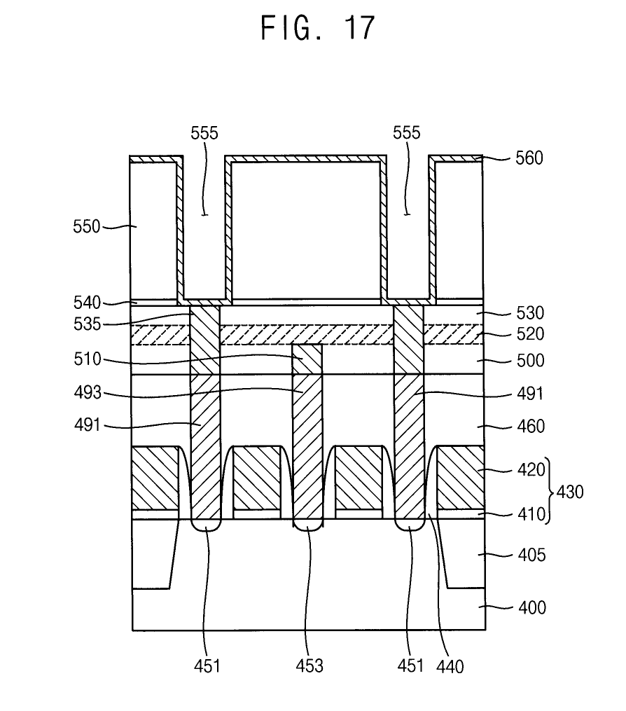

Referring to FIG. 16, a capacitor contact 535 may be formed through the second and third insulating interlayers 500 and 530 to contact a top surface of the first contact plug 491, and an etch stop layer 540 and a mold layer 550 may be sequentially formed on the capacitor contact 535 and the third insulating interlayer 530.

In example embodiments, the capacitor contact 535 may be formed by etching the second and third insulating interlayers 500 and 530 to form a second opening (not shown) exposing the top surface of the first contact plug 491, forming a fourth conductive layer to sufficiently fill the second opening, and planarizing the fourth conductive layer until a top surface of the third insulating interlayer 530 may be exposed. The capacitor contact 535 may be formed to include doped polysilicon, a metal, e.g., tungsten, etc.

The etch stop layer 540 may be formed to include a nitride, e.g., silicon nitride. The mold layer 550 may be formed to include an oxide, e.g., silicon oxide.

Processes substantially the same as or similar to those illustrated with reference to FIGS. 1 to 3 may be performed to partially remove the mold layer 550 and the etch stop layer 540. Thus, a third opening 555 may be formed to expose a top surface of the capacitor contact 535.

In example embodiments, the third opening 555 may be formed by forming a fourth hard mask 552 on the mold layer 550 to partially expose a top surface of the mold layer 552, and etching the mold layer 550 using an etching gas including fluorine and the fourth hard mask 552 as an etching mask. The fourth hard mask 552 may be formed to include carbon and boron, and may include from about 10 weight percent to about 50 weight percent of boron. The etching gas may include fluorocarbon (CₓF_{y}) and/or hydrofluorocarbon (CₓH_{y}F_{z}). A blocking layer 554 may be formed on the fourth hard mask 552 due to the formation of etching by-products.

Referring to FIG. 17, processes substantially the same as or similar to those illustrated with reference to FIGS. 4 to 6, FIGS. 7 to 8, or FIGS. 9 to 10 may be performed to remove the blocking layer 554 and the fourth hard mask 552.

When the third opening 555 is formed, even though the blocking layer 554 is formed, the fourth hard mask 552 may be easily removed with no popping.

A lower electrode layer 560 may be formed on an inner wall of the third opening 555 and the mold layer 540. The lower electrode layer 560 may be formed to include a metal, e.g., tungsten, titanium, tantalum, etc., a metal nitride, e.g., tungsten nitride, titanium nitride, tantalum nitride, etc., or doped polysilicon.

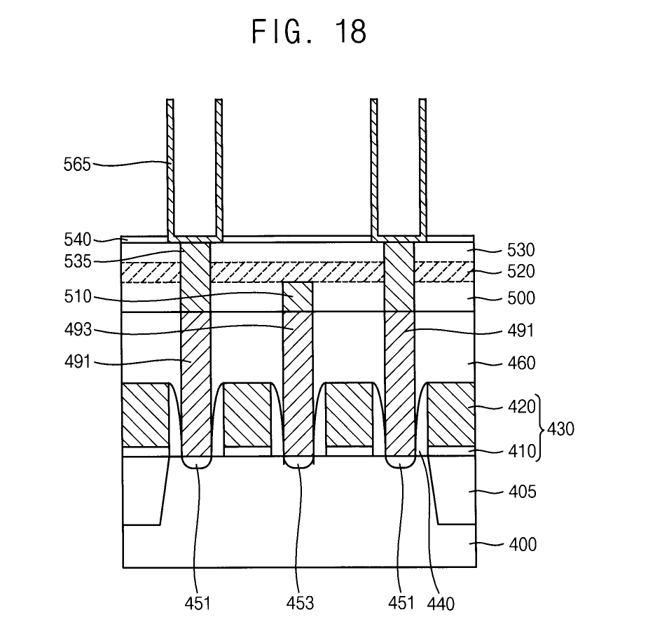

Referring to FIG. 18, a sacrificial layer (not shown) may be formed on the lower electrode layer 560 to sufficiently fill the third opening 555, and the sacrificial layer and the lower electrode layer 560 may be planarized until a top surface of the mold layer 550 may be exposed to form a lower electrode 565 and a sacrificial layer pattern (not shown). Thus, the lower electrode 565 may be formed on the inner wall of the third opening 555 to partially fill the third opening 555 and contact a top surface of the capacitor contact 535. The sacrificial layer pattern may be formed on the lower electrode 565 to fill a remaining portion of the third opening 555.

The mold layer 550 and the sacrificial layer pattern may be removed by, e.g., a wet etch process. The lower electrode 565 may not be removed but remain by the wet etch process.

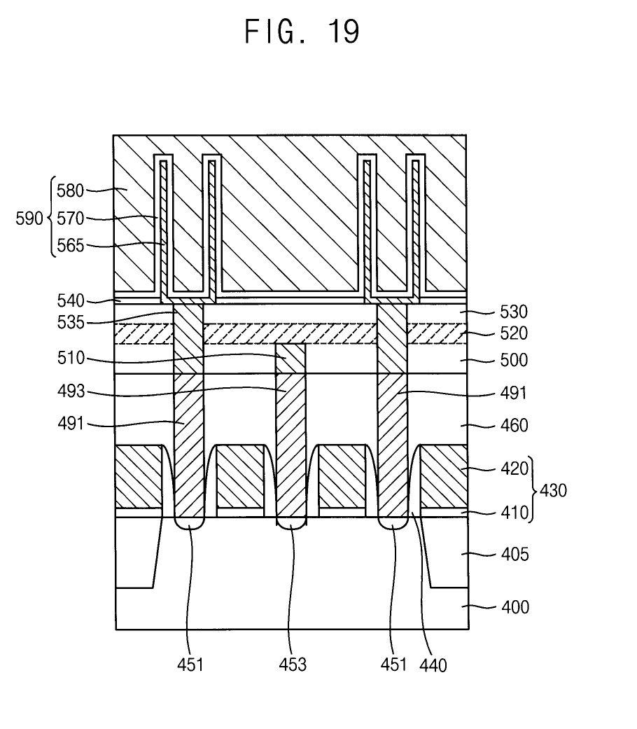

Referring to FIG. 19, a dielectric layer 570 and an upper electrode 580 may be sequentially formed on the lower electrode 565. Thus, a capacitor 590 including the lower electrode 565, the dielectric layer 570 and the upper electrode 580 may be formed.

The dielectric layer 570 may be formed on the lower electrode 565 and the etch stop layer 540 to include an insulating material, e.g., an oxide such as silicon oxide, metal oxide, etc., and/or a nitride such as silicon nitride, metal nitride, etc. The metal may include, e.g., aluminum, zirconium, titanium, hafnium, etc.

The upper electrode 580 may be formed to include a material substantially the same as that of the lower electrode 565, e.g., a metal, a metal nitride, doped polysilicon, etc.

As illustrated above, when a layer, including silicon oxide and/or silicon nitride, is etched to form a contact hole and/or an opening, etching by-products and/or a blocking layer may be formed. But the first and second plasma treatments may be sequentially performed to prevent pollution and defect of a semiconductor device.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses (using the phrase “means for . . . ”) are intended to cover the structures described herein as performing the recited function and not only structural equivalents but also equivalent structures. It is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of manufacturing, the method comprising:
forming a hard mask on a substrate;
performing a first plasma treatment on the hard mask while controlling the hard mask to be at a first temperature; and
performing a second plasma treatment on the hard mask while controlling the hard mask to be at a second temperature higher than the first temperature.

2. The method of claim 1, wherein the hard mask includes carbon and boron.

3. The method of claim 2, wherein the boron is in an amount in a range from 10 weight percent to about 50 weight percent.

4. The method of claim 2, further comprising:
forming an object layer on the substrate; and
patterning the object layer using an etching gas including fluorine and the hard mask as an etching mask.

5. The method of claim 4, wherein a blocking layer including fluorochemicals is formed on the hard mask as the object layer is patterned.

6. The method of claim 5, wherein performing the first plasma treatment includes removing the blocking layer.

7. The method of claim 1, wherein the first and second plasma treatments are performed using different etching gases.

8. The method of claim 7, wherein the first plasma treatment is performed using at least one of O₂ plasma and NF₃ plasma.

9. The method of claim 8, wherein the second plasma treatment is performed using H₂O plasma.

10. The method of claim 1, wherein the first temperature is in a range of about 100° C. to about 300° C., and the second temperature is in a range of about 400° C. to about 500° C.

11. The method of claim 1, wherein the first and second plasma treatments are performed in-situ.

12. The method of claim 4, wherein the patterning and the first and second plasma treatments are performed in the same chamber.

13. The method of claim 4, wherein the etching gas comprises fluorocarbon (CₓF_{y}) and/or hydrofluorocarbon (CₓH_{y}F_{z}).

14. A method of manufacturing, the method comprising:
forming a hard mask on a substrate;
loading the substrate onto a chuck in a chamber via an entrance at a side of the chamber, the chuck having a lift pin at an upper portion thereof;
moving the lift pin in a first direction substantially perpendicular to a top surface of the substrate so that the substrate is spaced apart from the chuck;
introducing a first etching gas into an inside of the chamber via a first inflow track of the chamber and applying a high frequency voltage to electrodes on an outer top surface of the chamber and under the chuck, respectively, to perform a first plasma treatment while controlling the chuck to have a first temperature by a temperature controller disposed at the chamber and connected to the chuck;
moving the lift pin in a second direction substantially opposite to the first direction so that the substrate contacts the chuck; and
removing the hard mask by introducing a second etching gas into the inside of the chamber via a second inflow track of the chamber and applying a high frequency voltage to electrodes to perform a second plasma treatment while controlling the chuck have the first temperature.

15. The method of claim 14, wherein the first plasma treatment is performed on the substrate at a second temperature lower than the first temperature and with the substrate spaced apart from the chuck.

16. The method of claim 14, wherein the second plasma treatment is performed on the substrate at a third temperature higher than the first temperature and with the substrate kept spaced apart from the chuck.

17. The method of claim 14, wherein the hard mask includes carbon and boron.

18. The method of claim 17, further comprising:
forming an object layer on the substrate; and
patterning the object layer using an etching gas including fluorine and the hard mask as an etching mask.

19. The method of claim 18, wherein a blocking layer including fluorochemicals is formed on the hard mask as the object layer is patterned, and wherein performing the first plasma treatment includes removing the blocking layer.

20. A method of manufacturing, the method comprising:
forming a hard mask on the substrate;
patterning an object layer using the hardmask, the patterning causing an etchant byproduct to be formed on a surface of the hard mask;
removing the etchant byproduct with a first plasma with the substrate controlled to be at a first temperature, the first plasma being formed of a first plasma material;
increasing the temperature of the substrate above the first temperature;
removing the hard mask by exposing the hard mask to a second plasma while the substrate is at the increased temperature, the second plasma being formed of a second plasma material, different from the first plasma material.
